(19) United States
(12) Patent Application Publication
(10) Pub. No.: US 2016/0186319 A1
(43) Pub. Date: Jun. 30, 2016

(54) SILICON CARBIDE STACK BOTTOM SEAL ARRANGEMENT

(71) Applicant: REC Silicon Inc, Moses Lake, WA (US)

(72) Inventors: Michael V. Spangler, Soap Lake, WA (US); Jeffrey A. Hansen, Moses Lake, WA (US); Matthew J. Miller, Moses Lake, WA (US)

(73) Assignee: REC Silicon Inc, Moses Lake, WA (US)

(21) Appl. No.: 14/977,287

(22) Filed: Dec. 21, 2015

Related U.S. Application Data
(63) Continuation of application No. PCT/US2015/037782, filed on Jun. 25, 2015.
(60) Provisional application No. 62/099,057, filed on Dec. 31, 2014.
(60) Provisional application No. 62/099,057, filed on Dec. 31, 2014.

(51) Int. Cl. C23C 16/44; C23C 16/455; C23C 16/24

(52) U.S. Cl. CPC C23C 16/4409; C23C 16/24; C23C 16/45563

(57) ABSTRACT

Fluidized bed reactor systems for producing high purity silicon-coated particles are disclosed. A vessel has an outer shell, an insulation layer inwardly of the outer shell, a concentric inner shell inwardly of the outer shell, and a concentric liner that is positioned inwardly of the inner shell and that defines a reactor chamber. The inner shell and liner are sealed together at their bottoms by an O-ring seal arrangement to prevent gas in the reactor chamber from entering a space between the inner shell and the liner. A central inlet nozzle produces a vertical gas plume in the reactor chamber.

### CROSS REFERENCE TO RELATED APPLICATIONS

This is a continuation of International Application No. PCT/US2015/037782, filed Jun. 25, 2015, which claims the benefit of U.S. Provisional Application No. 62/099,057, filed Dec. 31, 2014.

This claims the benefit of U.S. Provisional Application No. 62/099,057, filed Dec. 31, 2014.

Both of the above-referenced prior applications are incorporated herein in their entireties by reference.

### FIELD

The present disclosure relates to reactors for pyrolytic decomposition of a silicon-bearing gas in a fluidized bed to produce silicon-coated particles.

### BACKGROUND

Pyrolytic decomposition of silicon-bearing gas in fluidized beds is an attractive process for producing polysilicon for the photovoltaic and semiconductor industries due to excellent mass and heat transfer, increased surface for deposition, and continuous production. Compared with a Siemens-type reactor, the fluidized bed reactor offers considerably higher production rates at a fraction of the energy consumption. The fluidized bed reactor can be continuous and highly automated to significantly decrease labor costs.

One such fluidized bed reactor is described in WO2011063007A2 and shown in FIG. 1. In that reactor, an inner shell extends generally vertically through reactor and is generally cylindrical with a generally circular cross-section. A liner, located inwardly of the inner shell, extends generally vertically through reactor and also is generally cylindrical with a generally circular cross-section. The liner defines the reactor chamber and protects the inner shell from attrition by silicon-coated particles. The liner is constructed from a material or materials selected to avoid contamination of the silicon particles. The liner thus protects seed and product particles in the fluidized bed from contamination by the inner shell and/or vessel wall materials.

The inner shell and the liner of WO2011063007A2 are separated by a gap such that an annular space, of cylindrical shape, is provided between the inner shell and the liner. A seal is provided at the bottom of the inner shell to keep gas and particulate material from entering the space from the reaction chamber.

Problems can occur because the inner shell and the liner are made of different materials that have different thermal coefficients of expansion and because, during operation of the reactor, gas pressure in the reaction chamber differs from gas pressure in the space between the inner shell and the liner.

A particular problem in such a system is ineffectiveness of the seal between the inner shell and the liner. In such a system, a typical seal arrangement is a flat gasket located between two flat horizontal metal surfaces. This arrangement is problematic because the gasket is held in place only by friction between flat surfaces. Fluid bed reactors produce substantial vibrations during operation. As a result, the flat gasket slowly slides out from between the two flat metal surfaces as vibrations and pressure surges cause members at the bottom of the reactor to shift around.

It has also been a problem that the inwardly facing edge surface of a flat gasket can come into direct contact with silicon particles inside the reactor chamber when there is a process upset. The gasket is overheated by direct contact with hot silicon particles and breaks down. Once the innermost region of a flat gasket breaks down and sloughs off, the hot silicon particles act on the next layer and eventually “burn” through the entire gasket, thereby destroying the integrity of the seal. This also affects product quality. Bits of broken-off gasket material enter the reactor chamber and contaminate the silicon particles contained therein.

Thus there is a need for a seal arrangement that can work effectively under the conditions present in a fluidized bed reactor for the deposition silicon.

### SUMMARY

Fluidized bed reactor systems for production of high purity silicon-coated particles are disclosed. The fluidized bed reactor systems include a liner constructed of a material that minimizes contamination of particles in the fluid bed. In that reactor, an inner shell extends generally vertically through reactor and is generally cylindrical with a generally circular cross-section. A liner, located inwardly of the inner shell, extends generally vertically through reactor and also is generally cylindrical with a generally circular cross-section. The liner defines the reactor chamber and protects the inner shell from attrition due to contact with silicon-coated particles.

One system comprises a vessel that has an outer shell, an insulation layer that is adjacent to an inner surface of the outer shell, a generally cylindrical inner shell located inwardly of the insulation layer and positioned inwardly of a plurality of heaters. Advantageously, the inner shell is made of a high temperature alloy. A generally cylindrical liner is located within the inner shell, with an annular space, of cylindrical shape, provided between the inner shell and the liner. The liner defines a reaction chamber that contains a plurality of seed particles and/or silicon-coated particles. The liner may be made of non-contaminating materials including, but not limited to, quartz, silicon, low-nickel alloy, high-temperature alloy, cobalt alloy, silicon nitride, graphite, silicon carbide, molybdenum, or a molybdenum alloy.

The bottom end surfaces of the inner shell and liner are supported near the bottom of the reactor. A support assembly includes components arranged to seal off the bottom of the space between the inner shell and liner to block gas and particulate material from entering the space. The assembly advantageously will include one or more O-rings between facing surfaces of adjacent steel reactor members. Each O-ring is contained in an annular channel or groove defined in a horizontal surface of a steel reactor part. O-rings are located at a distance radially outwardly of the surface or surfaces that define the reactor chamber, so the O-rings are not touched by hot silicon particles located inside the chamber. As a result, there is no contamination of the silicon particles due to contact with an O-ring. The integrity of such an O-ring is maintained because the hot particles cannot touch the O-ring and because the steel parts will absorb most of the heat and conduct it away. Advantageously, O-rings are provided at both upper and lower surfaces of a steel seal ring that is located between the inner shell and the liner. The steel seal ring assists with heat dissipation. Because each O-ring is located in an annular groove, the O-ring cannot slide out of position.

The system further includes a reaction gas inlet nozzle, one or more inlets for fluidizing gas such as a plurality of fluidization nozzles, and at least one outlet for silicon product removal.

The foregoing will be better understood from the following detailed description, which proceeds with reference to the accompanying drawings.

### BRIEF DESCRIPTION OF THE DRAWINGS

FIG. 1 is a schematic cross-sectional elevational view of a fluidized bed reactor.

FIG. 2 is an enlarged cross-sectional elevational view of a portion of a fluidized bed reactor, depicting an outer shell, an insulation layer, an inner shell with an inner shell expansion device, and a liner.

FIG. 3. is an enlarged partial cross-sectional elevational view of a portion of the fluidized bed reactor of FIG. 2, depicting details of a bottom support system for the inner shell and the liner.

FIG. 4 is a partial cross-sectional view taken along line 4-4 of FIG. 3.

### DETAILED DESCRIPTION

Disclosed herein are fluidized bed reactor systems for the formation of polysilicon by pyrolytic decomposition of a silicon-bearing gas and deposition of silicon onto fluidized silicon particles or other seed particles (e.g., silica, graphite, or quartz particles).

Silicon-coated particles are grown by pyrolytic decomposition of a silicon-bearing gas within a reactor chamber and deposition of silicon onto particles within a fluidized bed in the chamber. Initially the deposition is onto small seed particles. Deposition continues until particles are grown to a size appropriate for commercial use, whereupon the grown particles are harvested.

Seed particles may have any desired composition that is suitable for coating with silicon. Suitable compositions are those that do not melt or vaporize, and do not decompose or undergo a chemical reaction under the conditions present in the reactor chamber. Examples of suitable seed particle compositions include, but are not limited to, silicon, silica, graphite, and quartz.

Silicon is deposited on the particles by decomposition of a silicon-bearing gas selected from the group consisting of silane (SiH₄), disilane (Si₂H₆), higher order silanes (SiₙH₂ₙ₊₂), dichlorosilane (SiH₂Cl₂), trichlorosilane (SiHCl₃), silicon tetrachloride (SiCl₄), dibromosilane (SiH₂Br₂), tribromosilane (SiHBr₃), silicon tetrabromide (SiBr₄), diiodosilane (SiH₂I₂), triiodosilane (SiHI₃), silicon tetraiodide (SiI₄), and mixtures thereof. The silicon-bearing gas may be mixed with one or more halogen-containing gases, defined as any of the group consisting of chlorine (Cl₂), hydrogen chloride (HCl), bromine (Br₂), hydrogen bromide (HBr), iodine (I₂), hydrogen iodide (HI), and mixtures thereof. The silicon-bearing gas may also be mixed with one or more other gases, including hydrogen (H₂) or one or more inert gases selected from nitrogen (N₂), helium (He), argon (Ar), and neon (Ne). In particular embodiments, the silicon-bearing gas is silane, and the silane is mixed with hydrogen.

The silicon-bearing gas, along with any accompanying hydrogen, halogen-containing gases and/or inert gases, is introduced into the central chamber of a fluidized bed reactor and thermally decomposed within the chamber to produce silicon which deposits upon seed particles inside the chamber.

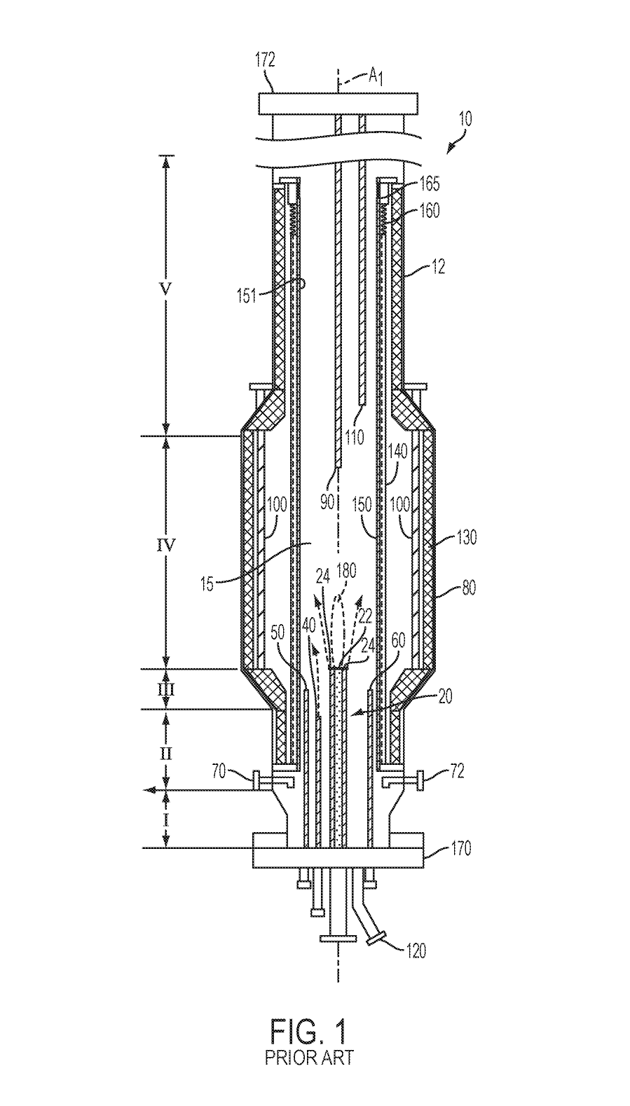

FIG. 1 shows the general configuration of a fluidized bed reactor 10 for production-coated particles. The reactor of FIG. 1, which is similar to the reactor of WO2011063007A2, is particularly well suited for silicon production by the pyrolytic decomposition of silane. The reactor 10 includes a vessel 12 that extends generally vertically from a base 170 to a top head 172, has a vertical central axis A₁, and may have cross-sectional dimensions that are different at different elevations. The reactor shown in FIG. 1 has five regions I-V of differing cross-sectional dimensions.

The reactor 10 has an outer shell 80. One or more heaters 100 are positioned inwardly of outer shell 80 in region IV. In some systems, heaters 100 are radiant heaters. The reactor 10 also may include an internal bed heater 90. A layer of insulation 130 is positioned along the inner surface of outer shell 80. The insulation layer 130 thermally insulates outer shell 80 from radiant heaters 100.

An inner shell 140 extends vertically through regions II-V of the reactor 10. The illustrated inner shell is generally cylindrical with a generally circular cross-section. The inner shell can be constructed from any suitable material that can tolerate the conditions within reactor 10 and is well-suited to the high temperatures utilized to transfer heat into the fluid bed. Because the pressures internal and external to the inner shell are similar, the inner shell can be thin. In some systems, the inner shell has a thickness of 5-10 mm, such as 6-8 mm.

A liner 150, which may be removable, is positioned within the inner shell 140 at a small distance from the inner surface 142 of the inner shell 140. The illustrated liner 150 is generally cylindrical, has a generally circular horizontal cross-section, is concentric with the inner shell 140, extends generally vertically through regions II-V. The liner 150 has an inner surface 151 that at least partially defines a reactor chamber 15.

The liner 150 provides containment of the fluidized bed and separates it from other components of the reactor. In particular, the liner 150 protects the inner shell 140 from attrition by silicon-coated particles and seed particles in the fluidized bed and protects the particles from contamination by the inner shell and/or vessel wall materials. The liner 150 is constructed from a material selected to not contaminate the particles and preferably is made of a material that can sustain a temperature of 1600° F. (870° C.) and maintain stability. Suitable materials for liner 150 include, but are not limited to, non-contaminating materials including, but not limited to, quartz, silicon, low-nickel alloy, high-temperature alloy, cobalt alloy, silicon nitride, graphite, silicon carbide, molybdenum, or a molybdenum alloy. In particular systems, the liner is constructed from silicon carbide, molybdenum, or a molybdenum alloy. Silicon carbide advantageously has a low thermal expansion coefficient of 2.2-2.4×10-6/° F., or 3.9-4.0×10-6/° C.

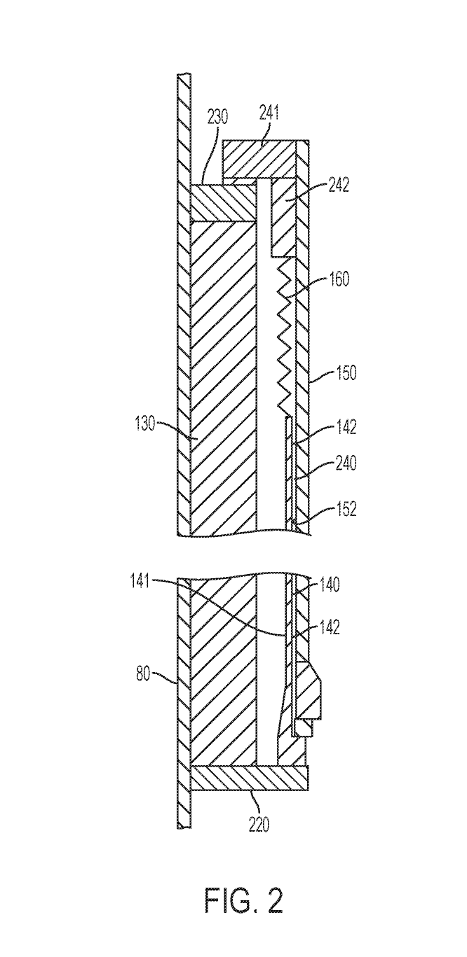

FIG. 2 shows the configuration of an improved reactor system from its outer shell 80 to its liner 150, including an improved bottom seal. The insulation layer 130 is disposed adjacent to outer shell 80 and is supported between a lower seal support ring 220 and an upper seal ring 230. The inner shell 140 is positioned inwardly of the insulation layer 130 and is supported by the lower seal support ring 220. The inner shell 140 has an outer surface 141 and an inner surface 142. The illustrated surfaces 141, 142 are concentric and generally cylindrical, except for a bottom portion of the inner shell 140 where the surfaces diverge. The liner 150 is positioned inwardly of the inner shell 140. There is a narrow gap, e.g., 1.5 mm as measured horizontally, between the inner shell 140 and liner 150 to allow for horizontal thermal expansion. Due to the gap, an annular space 240 exists between the bottom seal and the top of the inner shell 140. In the illustrated embodiment, the side boundaries of the annular space 240 are defined by two vertically extending concentric surfaces 142, 152 that are circular cylinders. The various components of the bottom seal assembly together provide a seal that extends from the inner shell 140 to the liner 150 to block gas from passing from the bottom of the reactor chamber 15 into the space 240 between the inner shell 140 and the liner 150.

Each of the outer shell 80, inner shell 140 and lower seal support ring 220 is constructed from a material that is suitable for tolerating the temperature gradients associated with heating the fluid bed and cooling the product. Suitable materials include, but are not limited to, austenitic stainless steel, high-temperature metal alloys such as INCOLOY® alloys, INCONEL® alloys, and cobalt alloys (e.g., RENE® 41).

Radiant heaters (not shown) may be disposed between the insulation layer 130 and the inner shell 140.

An expansion joint system includes an inner shell expansion device 160 that extends upwardly from the upper surface of the inner shell 140. Inner shell expansion device 160 can compress to allow for vertical thermal expansion of the inner shell 140 during operation of reactor 10. The device 160 need not provide a gas-tight seal.

The illustrated inner shell expansion device 160 extends between the inner shell 140 and an expansion support. The expansion support includes members 241, 242, that are attached securely to the upper seal ring 230. The expansion joint system accommodates the differential expansion of the inner shell 140 and the outer shell 80 of the reactor. The illustrated inner shell expansion device 160 is a generally cylindrical spring-type device having an inner diameter similar to the inner diameter of the inner shell 140. The inner shell expansion device 160 is configured to exert downward pressure on inner shell 140. In certain systems, the inner shell expansion device 160 is a helical coil of flat wire or a wave spring, i.e., a cylindrical stack of flat wires with waves in the wire.

As the temperature rises within the reactor, the inner shell 140 expands and inner shell expansion device 160 is pushed upward and compressed. Upon cooling, the inner shell 140 contracts and inner shell expansion device 160 extends. Inner shell expansion device 160 also exerts pressure on the inner shell 140. Optionally, an expansion spring 165 may be provided above the liner 150 to accommodate thermal expansion of the liner.

Lower end portions of the inner shell 140 and the liner 150 are supported and sealed so that gas does not flow from the fluid bed into the annular space 240 between the inner shell and the liner. The liner 150 has an annular bottom surface 154 that is ground to be smooth and planar to aid in forming a good bottom seal. In the illustrated system the bottom surface 154 of the liner 150 extends generally horizontally.

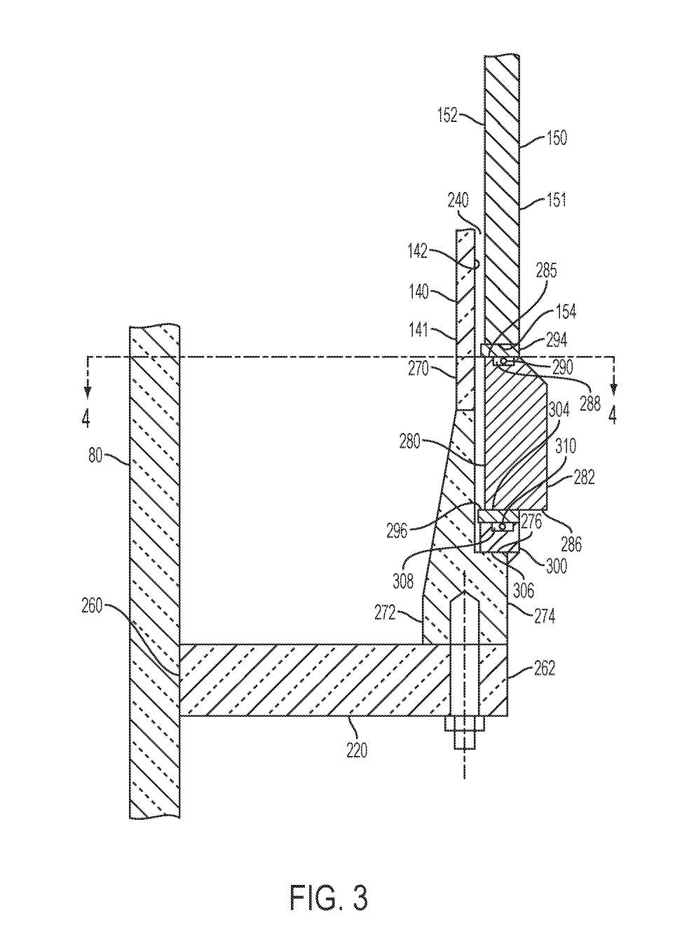

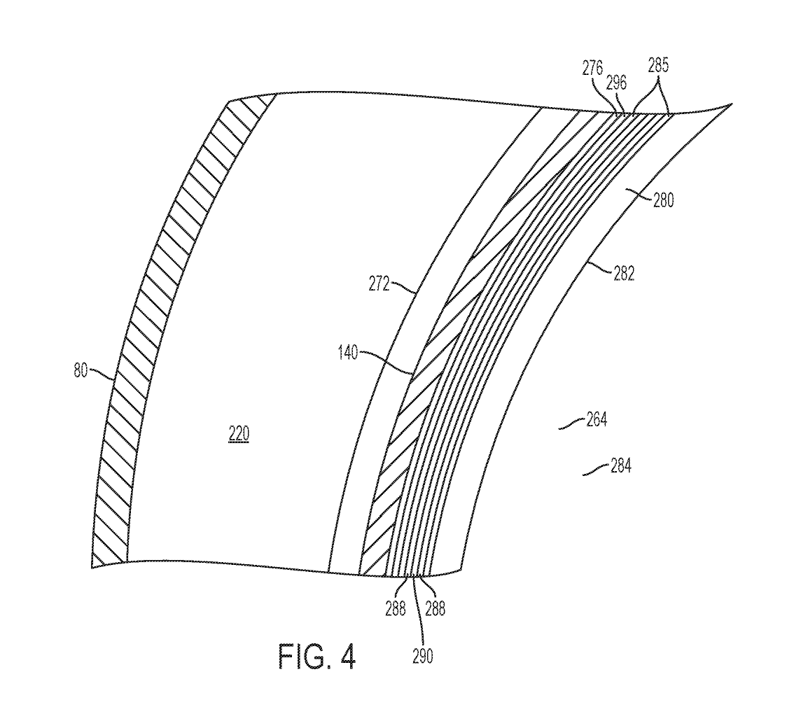

FIG. 3 shows the bottom seal arrangement of FIG. 2 in greater detail. In the illustrated arrangement the liner 150 is supported by the inner shell 140 and one or more gaskets are provided between the liner 150 and the inner shell 140 to provide a gas-tight seal. A support member, such as the illustrated lower seal support ring 220, is ring-shaped, is attached to the outer shell 80 at an elevation above the base 170, extends inwardly from the outer shell 80 in the manner of a flange, and supports the inner shell 140. The lower seal support ring 220 has an outer edge surface 260 that faces the outer shell 80 and an inner edge surface 262 that defines a generally vertically extending central opening 264, indicated in FIG. 4, through the lower seal support ring 220. The inner shell 140 has an upper portion 270 and a lower portion 272. The illustrated lower portion 272 has a flat bottom surface that rests on the seal support ring 220. The lower portion 272 includes a flange 274 that protrudes radially inwardly relative to the upper portion 270, with the flange 274 having a generally horizontal, upwardly facing ledge surface 276. The liner 150 is supported by the ledge surface 276. In the advantageous arrangement shown in FIG. 3, the lower portion 272 of the inner shell 140 is thicker, as measured horizontally, than the upper portion 270. The greater thickness of the lower portion 272 gives the inner shell 140 a broader base to rest on the seal support ring 220. Advantageously, the lower portion 272 will be sufficiently thick that the base of the inner shell 140 can define bores to receive bolts or can support studs for securing the inner shell to the vessel, such as to the seal support ring 220. In the illustrated system, the outer surface 141 flares toward the bottom of the inner shell 140 to provide additional thickness.

In the illustrated system, an annular member is connected to the inner shell 140 to provide support for the liner 150. The illustrated annular member is a seal ring 280 that is located between the liner 150 and the ledge surface 276 with the seal ring 280 supported by the ledge surface 276 and the liner 150 supported by the seal ring 280. The seal ring 280 has an annular top surface 285 and an annular bottom surface 286, both of which surfaces are generally flat and extend generally horizontally. The seal ring 280 also has an annular inner edge surface 282 that defines a generally vertically extending opening 284, indicated in FIG. 4, through the seal ring 280. The seal ring 280 may be ferritic stainless steel, such as grade 410 stainless steel.

The top surface 285 of the seal ring 280 defines at least one annular upwardly opening channel. In the system shown in FIGS. 3-4 the top surface 285 defines one circular channel 288. An O-ring 290, sometimes referred to as an “upper O-ring,” is provided in the annular upwardly opening channel 288. The O-ring engages surfaces located above and below the O-ring to form a seal between those surfaces. As alternatives, plural channels could be provided in the top surface 285; plural O-rings could be provided between the liner 150 and the sealing ring 280. The O-ring 290 may be made from any suitable material. In particular, the O-ring 290 may be hollow core stainless steel or may be a perfluoroelastomer material such as DuPont™ Kalrez® perfluoroelastomer (FFKM).

The system may also include an annular intermediate ring 300 as best seen in FIG. 3. The illustrated intermediate ring 300 is located between the seal ring 280 and the ledge surface 276 with the intermediate ring 300 being supported by the ledge surface 276 and the seal ring 280 being supported by the intermediate ring 300. The illustrated intermediate ring has a top surface 304 that defines at least one annular upwardly opening channel 308. An O-ring 310, sometime referred to as a “lower O-ring,” is provided in one or more of the annular upwardly opening channels 308. The O-ring engages surfaces located above and below the O-ring to form a seal between those surfaces. In the embodiment of FIGS. 3-4, one O-ring 310 is provided in one channels 308. As alternatives, plural channels 308 could be provided; plural O-rings could be provided. The O-ring 310 may be made of a polymer such as DuPont™ Viton® fluoroelastomer or may be a perfluoroelastomer material such as DuPont™ Kalrez® perfluoroelastomer (FFKM).

In the illustrated embodiment, an annular upper gasket 294 is located between the seal ring 280 and the liner 150, primarily to protect the O-ring from abrasion due to contact with the lower surface 154 of the liner 150. An annular lower gasket 296 is located between the seal ring 280 and the ledge surface 276. In particular, the annular upper gasket 294 is located between the top surface 285 of the seal ring 280 and the liner 150; and the annular lower gasket 296 is located between the bottom surface 286 of the seal ring 280 and the ledge surface 276. Such gaskets typically are not necessary and may be omitted. But one or both of the gaskets 294, 296 may be provided as needed. The gaskets may be made of a graphite material, such as GRAFOIL® flexible graphite gasketing material, which is sufficiently rigid that the gaskets do not slide sideways during operation of the reactor. In a system without an upper gasket 294, the lower surface 154 of the liner 150 rests on the top surface 285 of the seal ring 280, with the one or more O-rings 290 being in contact with and forming a seal between the liner 150 and the seal ring 280. In a system without a lower gasket 296, the bottom surface 286 of the seal ring 280 rests on top of the intermediate ring 300, with the one or more O-rings 310 being in contact with and forming a seal between the seal ring 280 and the intermediate ring 300.

An inlet nozzle 20 is provided for injection of a primary gas through a central passageway 22 and a secondary gas through an annular passageway 24 surrounding central passageway 22. Advantageously, nozzle 20 is positioned such that silane is injected in a plume 180 near the vertical centerline A₁ of the reactor 10. In particular arrangements, central inlet nozzle 20 comprises two substantially cylindrical tubes that are substantially circular in cross-section. The primary gas is silicon-bearing gas or a mixture of silicon-bearing gas, hydrogen and/or an inert gas (e.g., helium, argon). The primary gas also may include a halogen-containing gas. The secondary gas typically has substantially the same composition as the hydrogen and/or inert gas in the primary gas mixture. In particular arrangements, the primary gas is a mixture of silane and hydrogen, and the secondary gas is hydrogen.

The illustrated reactor 10 further includes a plurality of fluidization gas nozzles 40. Additional hydrogen and/or inert gas can be delivered into the reactor through the fluidization nozzles 40 to provide sufficient gas flow to fluidize the particles within the reactor bed.

Also provided are a sample nozzle 50 through which product is sampled and one or more pressure nozzles 60 for monitoring pressure within the reactor, which nozzles are laterally displaced from the central inlet nozzle 20. One or more purge gas/cooling gas nozzles 70, 72 are located below the fluidization nozzles 40 and extend radially through outer shell 80 and into the reactor 10.

The reactor 10 has a seed nozzle 110 through which seed particles can be introduced into the reactor chamber 15. The reactor 10 also has one or more product outlets 120 for removing silicon-coated particles from the reactor chamber 15.

In operation, a bed of seed particles is provided inside the reactor chamber 15 and is fluidized by gas injected through the solitary central inlet nozzle 20 and the supplemental fluidization nozzles 40. The contents of the reactor chamber 15 are heated. The silicon-bearing gas decomposes and deposits silicon on the seed particles in the fluidized bed. Cooling gas is introduced into the chamber 15 through cooling gas nozzles 70, 72.

It should be recognized that the illustrated reactor is only and example and should not be taken as limiting the scope of the invention. Rather, the scope of the invention is defined by the following claims.

1. A silicon deposition reactor system comprising:
a vessel having a base, a top head, and a generally tubular outer shell that extends generally vertically between the base and the top head;
a generally tubular inner shell located inwardly of the outer shell, the inner shell extending generally vertically and being supported by the vessel;
a generally tubular liner located inwardly of the inner shell, the liner extending generally vertically and being supported by the inner shell, the liner having an inner surface that at least partially defines a chamber suitable to contain a plurality of silicon particles in a fluidized bed;
at least one nozzle for injecting gas into the chamber; and
at least one outlet for removing gas from the chamber.

2. The system of claim 1 wherein:
the inner shell has an upper portion and a lower portion, the lower portion including a flange that protrudes radially inwardly relative to the upper portion, with the flange having a generally horizontal, upwardly facing ledge surface; and
the liner is supported by the ledge surface.

3. The system of claim 2 further comprising a seal ring located between the liner and the ledge surface such that the seal ring is supported by the ledge surface and the liner is supported by the seal ring, the seal ring having an annular inner edge surface that defines a generally vertically extending opening through the seal ring.

4. The system of claim 3 wherein:
the seal ring has an annular top surface and an annular bottom surface;
the top surface of the seal ring defines at least one annular upwardly opening channel; and
an O-ring is located in at least one annular upwardly opening channel to provide a seal between the liner and the seal ring.

5. The system of claim 3 further comprising an upper gasket located between the seal ring and the liner.

6. The system of claim 3 further comprising a lower gasket located between the seal ring and the ledge surface.

7. The system of claim 6 wherein the lower gasket is located between the bottom surface of the seal ring and the ledge surface.

8. The system of claim 3 further comprising an intermediate ring located between the seal ring and the ledge surface with the intermediate ring being supported by the ledge surface and the seal ring being supported by the intermediate ring.

9. The system of claim 8 wherein:
the intermediate ring has an annular top surface that defines at least one annular upwardly opening channel; and
an O-ring is located in at least one annular upwardly opening channel.

10. The system of claim 9 further comprising a lower gasket located between the seal ring and the O-ring that is located in at least one annular upwardly opening channel of the intermediate ring.

11. A silicon deposition reactor system comprising:
a vessel having a base, a top head, and a generally tubular outer shell that extends generally vertically between the base and the top head;
a generally tubular inner shell located inwardly of the outer shell, the inner shell extending generally vertically, being supported by the vessel, and having an inner surface;
a generally tubular liner located inwardly of the inner shell, the liner extending generally vertically, the liner having an outer surface that is spaced apart from the inner surface of the inner shell such that a tubular space is defined between the inner shell and the liner, the liner having an inner surface that at least partially defines a chamber suitable to contain a plurality of silicon particles in a fluidized bed, and the liner being sealed to the inner shell at a location near the bottom of the liner by an O-ring seal so that gas cannot enter the space from the chamber;
at least one nozzle for injecting gas into the chamber; and
at least one outlet for removing gas from the chamber.

12. The system of claim 11 wherein:
the liner is supported by the inner shell or by an annular member connected to the inner shell; and
the O-ring seal comprises at least one O-ring that is positioned to provide a seal between the liner and the inner shell or to provide a seal between the liner and the annular member connected to the inner shell.

13. The system of claim 12 wherein:
the inner shell has an upper portion and a lower portion, the lower portion including a flange that protrudes radially inwardly relative to the upper portion, with the flange having a generally horizontal, upwardly facing ledge surface; and
the liner is supported by the ledge surface.

14. The system of claim 12 comprising an annular member connected to the inner shell, the annular member being a seal ring located between the liner and the inner shell with the liner being supported by the seal ring, the seal ring having an annular inner edge surface that defines a generally vertically extending opening through the seal ring.

15. The system of claim 14 wherein:
the seal ring has an annular top surface and an annular bottom surface;
the top surface of the seal ring defines at least one annular upwardly opening channel; and
an O-ring is located in at least one annular upwardly opening channel to provide a seal between the liner and the seal ring.

16. The system of claim 14 further comprising an upper gasket located between the seal ring and the liner.

17. The system of claim 14 further comprising a lower gasket located between the seal ring and the inner shell.

18. The system of claim 14 further comprising an intermediate ring located between the seal ring and the inner shell with the seal ring being supported by the intermediate ring.

19. The system of claim 18 wherein:
the intermediate ring has an annular top surface that defines at least one annular upwardly opening channel; and
the system further comprises an O-ring that is located in at least one annular upwardly opening channel to provide a seal between the seal ring and the intermediate ring.

20. The system of claim 19 further comprising a lower gasket located between the seal ring and the O-ring that is located in at least one annular upwardly opening channel of the intermediate ring.

21. The system of claim 14 further comprising an O-ring seal that is located between the inner shell and the seal ring.
